(19) United States
(12) Patent Application Publication
(10) Pub. No.: US 2026/0190283 A1
(43) Pub. Date: Jul. 2, 2026

(54) COOLING SYSTEM FOR HOT-SWAPPABLE DEVICES

(71) Applicant: SK Hynix NAND Product Solutions Corp. (dba Solidigm), Rancho Cordova, CA (US)

(72) Inventors: Hardeep Singh, Vancouver (CA); Matthew Noland, Orangevale, CA (US); Axcan Gonzalez, Vancouver (CA)

(21) Appl. No.: 19/006,117

(22) Filed: Dec. 30, 2024

(51) Int. Cl. H05K 7/20; H05K 7/14

(52) U.S. Cl. CPC H05K 7/20254; H05K 7/1401; H05K 7/20272

(57) ABSTRACT

An apparatus and cooling system capable of cooling devices, wherein the cooling system includes a base plate, and for each respective device, a slot disposed on the base plate, the slot configured to couple to a connector of the respective device. For each respective device of the one or more devices, the cooling system includes an apparatus including a cold plate and a thermal interface material (TIM). The cold plate includes a first major face, a pin arranged along an axis extending in a direction parallel to the major face wherein the cold plate is rotatable about the axis, a liquid cooling inlet and a liquid cooling outlet. Each of the liquid cooling inlet and outlet is disposed at a first end of the cold plate. The TIM is disposed on the first major face and configured to transfer heat from the respective device to the cold plate.

### TECHNICAL FIELD

The present disclosure is directed to cooling systems for devices, particularly cooling systems with apparatuses for hot-swappable devices.

### SUMMARY

In accordance with the present disclosure, apparatuses and cooling systems are provided to improve the density, thermal cooling, and durability of cooling solutions for devices, such as hot-swappable devices (e.g., hot-swappable solid-state drive (SSD) devices or hot-swappable Peripheral Component Interconnect Express (PCIe) devices). The cooling system includes a base plate, and for each respective device, a slot is disposed on the base plate, and the slot is configured to couple to a connector of the respective device. For each respective device, the cooling system includes an apparatus including a cold plate and a thermal interface material (TIM). The cold plate includes a first major face, a pin arranged along an axis extending in a direction parallel to the major face wherein the cold plate is rotatable about the axis, a liquid cooling inlet and a liquid cooling outlet. Each of the liquid cooling inlet and outlet is disposed at the end of the cold plate. The TIM is disposed on the first major face and configured to transfer heat from the respective device to the cold plate. The apparatuses and cooling systems disclosed herein are provided to promote thermal transfer from devices (e.g., hot-swappable devices) that are in thermal contact with the apparatuses to the liquid cooling of the cold plates of the apparatuses, improving the overall thermal cooling capabilities of the cooling system.

### BRIEF DESCRIPTION OF THE DRAWINGS

The following description includes discussion of figures having illustrations given by way of example of implementations of embodiments of the disclosure. The drawings should be understood by way of example, and not by way of limitation. As used herein, references to one or more “embodiments” are to be understood as describing a particular feature, structure, and/or characteristic included in at least one implementation. Thus, phrases such as “in one embodiment” or “in an alternate embodiment” appearing herein describe various embodiments and implementations, and do not necessarily all refer to the same embodiment. However, they are also not necessarily mutually exclusive.

FIGS. 1A-1B show illustrative isometric view diagrams of an apparatus, in accordance with some embodiments of the present disclosure;

FIG. 2 shows an illustrative isometric view diagram of an apparatus, similar to that of FIG. 1, in thermal contact with a device, in accordance with some embodiments of the present disclosure;

FIG. 3 shows an illustrative isometric view diagram of a cooling system capable of cooling multiple devices, in accordance with some embodiments of the present disclosure; and

FIG. 4 shows an illustrative exploded view diagram of another apparatus, in accordance with some embodiments of the present disclosure.

### DETAILED DESCRIPTION

In accordance with the present disclosure, apparatuses, and cooling systems are provided to promote thermal transfer from (a) devices (e.g., hot-swappable devices) that are in thermal contact with the apparatuses to (b) the liquid cooling of the cold plates of the apparatuses, improving the overall thermal cooling capabilities of the cooling system. The cooling system disclosed herein is capable of cooling one or more devices (e.g., hot-swappable devices) and includes a base plate and a slot disposed on the base plate for each respective device (e.g., hot-swappable device) that the cooling system is capable of thermally cooling. Each slot is configured to receive and to be communicatively coupled with a connector of a respective device (e.g., an SSD device or PCIe device). The cooling system further includes an apparatus extending from the base plate for each respective device (e.g., hot-swappable device) that the cooling system is capable of thermally cooling.

Each apparatus includes a cold plate including a pin about which the cold plate is rotatable, a liquid cooling inlet to receive cooling liquid (e.g., thermal coolant), and a liquid cooling outlet to expel the received cooling liquid. The cold plate may include a liquid cooling loop that couples the liquid cooling inlet to the liquid cooling outlet, the liquid cooling loop arranged within the cold plate. The liquid cooling loop may be arranged within the cold plate of a respective apparatus such that heat transfers from (1) a device (e.g., hot-swappable device) that is in thermal contact with the respective apparatus to (2) the cooling liquid received through the liquid cooling inlet, passing through the liquid cooling loop, and thereafter expelled through the liquid cooling outlet. In some embodiments, the liquid cooling loop is in thermal contact with an exterior face (e.g., one of the major faces) of the cold plate, which is configured to be in thermal contact with a device (e.g., a hot-swappable device).

In some embodiments, when a cooling system includes more than one apparatus, for each respective apparatus, the liquid cooling outlet of the respective apparatus is coupled to the liquid cooling inlet of an adjacent apparatus. In such embodiments, the apparatuses of the cooling system are daisy-chained together such that the cooling liquid used within a first cold plate of a first apparatus passes on to be used within a second cold plate of a second apparatus, and the cooling liquid continues to be passed through the cold plates of each other apparatus of the cooling system. In such embodiments, the first cold plate of the first apparatus of the cooling system is configured to receive cooling liquid from a cooling liquid source, and a last cold plate of a last apparatus of the cooling system is configured to expel the cooling liquid to a cooling liquid drain.

In some embodiments, TIM is disposed on the exterior face of the cold plate to promote the thermal transfer of heat generated by the device (e.g., hot-swappable device) to the cold plate. The TIM may include an adhesive (e.g., pressure sensitive adhesive (PSA)) to physically couple the TIM to the exterior face of the cold plate. The TIM may include a non-adhesive side that is configured to come into thermal contact with the device (e.g., hot-swappable device). In some embodiments, the non-adhesive side includes a liner (e.g., a metallic liner or tape liner) or any other suitable material that permits the device to be inserted or removed from the respective slot without damaging the TIM of the apparatus.

Each apparatus may include an insertion feature configured to detect insertion of the device and cause the cold plate to avoid interference with the insertion of the device. In some embodiments, the insertion feature detects a translation motion of the device (e.g., hot-swappable device) during the insertion and removal of the device. When the device is fully inserted into a slot of the base plate, the apparatus may be configured to apply a force, using a spring, causing the cold plate to be in thermal contact with the device through TIM. During insertion and removal of the device, the insertion feature may be configured to provide clearance between the device and the cold plate of the respective apparatus.

The apparatus may also include a spring that is configured to induce a force onto the cold plate causing the TIM on the exterior face of the cold plate to be in thermal contact with the device. In some embodiments, the spring induces the force onto the cold plate of a respective apparatus in response to detecting the insertion of the device into a slot corresponding to the respective apparatus. The spring is one of a leaf spring, beam spring (e.g., a cantilever beam spring), a torque spring, an electronic force-inducing spring component, a magnetic force-inducing spring component, or an electro-magnetic force-inducing component that induces a force onto the cold plate, causing the TIM to be in thermal contact with the device. In some embodiments, the spring induces a force onto an exterior face of the cold plate that is opposite to the major face on which the TIM is applied. The spring of a respective apparatus is configured to induce a force on the cold plate of the respective apparatus to reduce a thermal interface resistance between a device (e.g., hot-swappable device) and the cold plate. In some embodiments, the spring may be any suitable force-inducing component, such as a mechanical spring component, an electrical spring component, a magnetic spring component, an electromagnetic spring component, or a gravitational spring component.

Each respective apparatus includes a pin about which the cold plate of the respective apparatus may rotate. In some embodiments, each pin of a respective apparatus includes (1) an inlet coupled to the liquid cooling inlet of the respective apparatus to receive liquid cooling and expel the liquid cooling into the liquid cooling inlet, and (2) an outlet coupled to the liquid cooling outlet of the respective apparatus to receive cooling liquid from the liquid cooling outlet and expel the cooling liquid.

In some embodiments, each apparatus may include a cold plate or any suitable thermal cooling solution that uses a cooling medium (e.g., cooling liquid or vapor), such as a vapor chamber and heat pipe.

For purposes of brevity and clarity, the features of the disclosure described herein are in the context of a cooling system with one or more apparatus, the cooling system capable of providing thermal cooling of one or more devices (e.g., hot-swappable devices). However, the principles of the present disclosure may be applied to any other suitable thermal cooling system contexts for providing cooling to one or more devices (e.g., hot-swappable devices).

In some embodiments, each device (e.g., hot-swappable device) may include a circuitry that functions as a storage device system (e.g., an SSD storage system), which includes a storage device such as an SSD device. In some embodiments, the circuitry of the device may include any suitable processing circuitry, which may include any suitable processing chip (e.g., an application-specific integrated circuit (ASIC) chip) or processing core. In some embodiments, the devices may be any suitable device that generates heat and may benefit from being placed in a thermal cooling system to reduce thermal throttling, therefore improving the performance of the device.

In some embodiments, each device may be a hot-swappable device or any other suitable device that can be added or removed from a slot of the cooling system without stopping, shutting down, or rebooting the cooling system.

An SSD is a data storage device that uses integrated circuit assemblies as memory to store data persistently. SSDs have no moving mechanical components, and this feature distinguishes SSDs from traditional electromechanical magnetic disks, such as hard disk drives (HDDs) or floppy disks, which contain spinning disks and movable read/write heads. Compared to electromechanical disks, SSDs are typically more resistant to physical shock, run silently, have lower access time, and less latency.

Many types of SSDs use NAND-based flash memory which retains data without power and includes a type of non-volatile storage technology. Quality of Service (QoS) of an SSD may be related to the predictability of low latency and consistency of high input/output operations per second (IOPS) while servicing read/write input/output (I/O) workloads. This means that the latency or the I/O command completion time needs to be within a specified range without having unexpected outliers. Throughput or I/O rate may also need to be tightly regulated without causing sudden drops in performance levels.

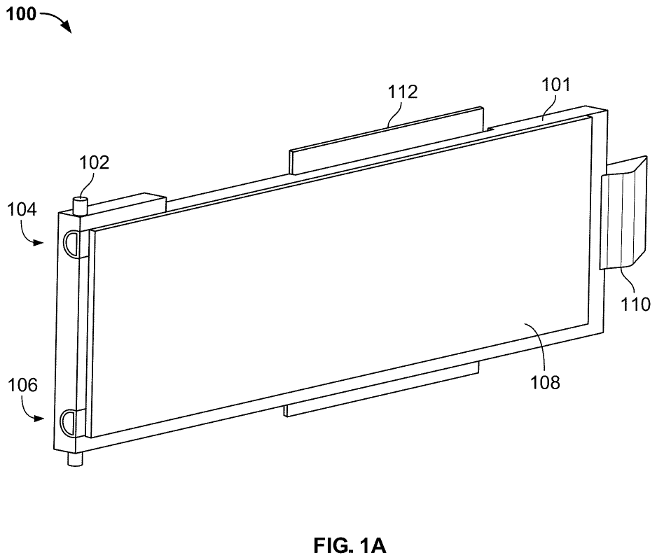

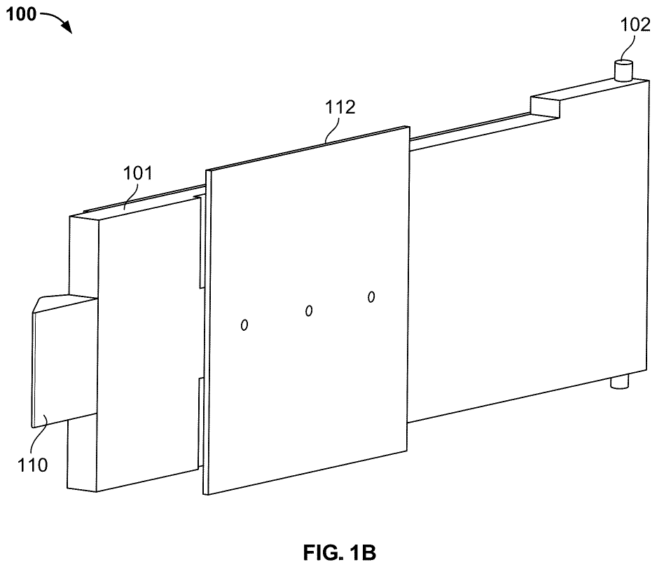

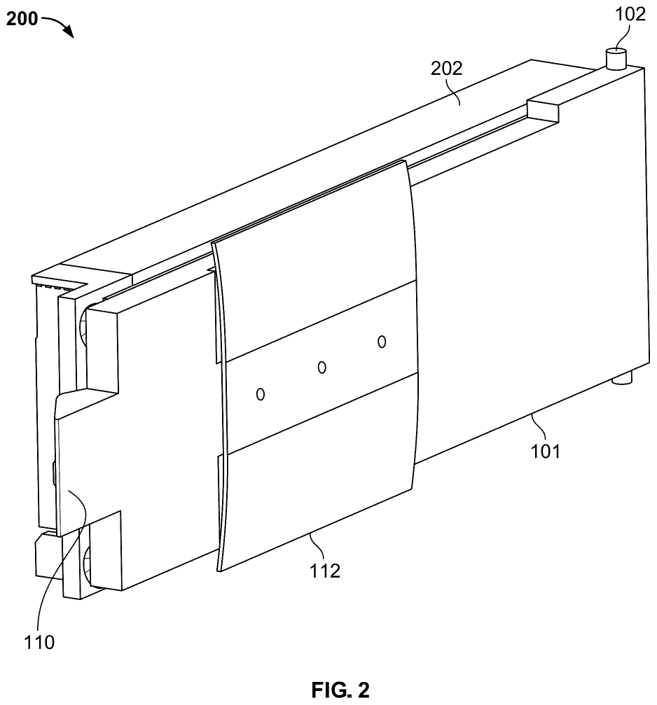

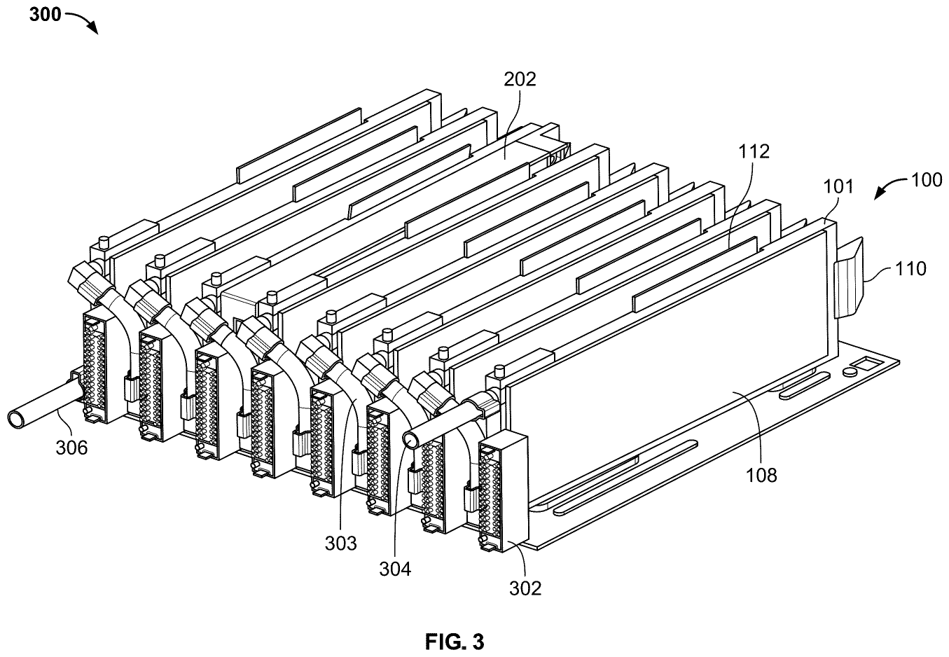

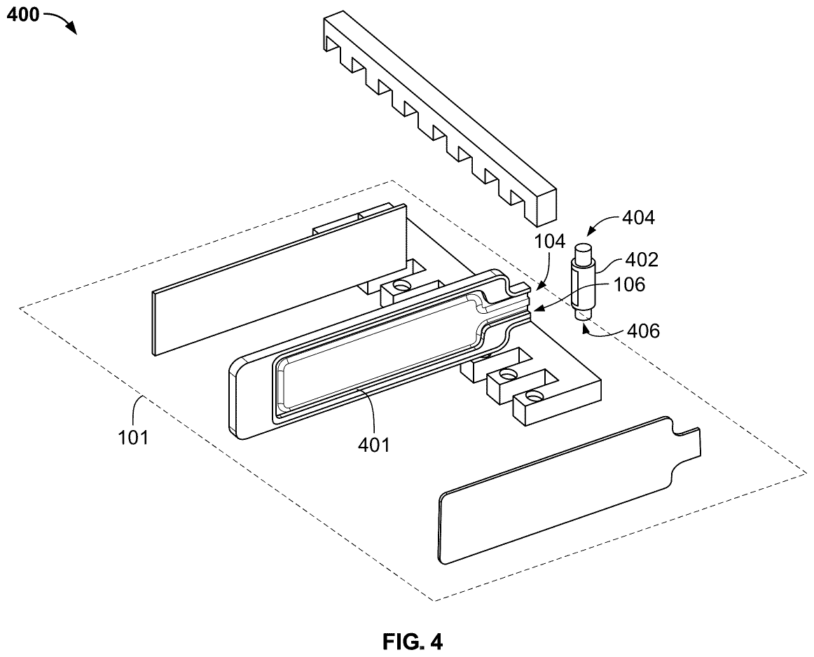

The subject matter of this disclosure may be better understood by reference to FIGS. 1-4.

FIGS. 1A-1B show illustrative isometric view diagrams of an apparatus 100, in accordance with some embodiments of the present disclosure.

Each apparatus 100 includes a cold plate 101 including a pin 102 about which the cold plate 101 is rotatable, a liquid cooling inlet 104 to receive cooling liquid (e.g., thermal coolant), and a liquid cooling outlet 106 to expel the received cooling liquid. Cold plate 101 may include a liquid cooling loop that couples the liquid cooling inlet 104 to the liquid cooling outlet 106. The liquid cooling loop may be arranged within the cold plate 101 of a respective apparatus (e.g., apparatus 100) such that heat transfers from (1) a device (e.g., hot-swappable device) that is in thermal contact with the respective apparatus (e.g., apparatus 100) to (2) the cooling liquid received through the liquid cooling inlet 104, passing through the liquid cooling loop, and thereafter expelled through the liquid cooling outlet 106. In some embodiments, the liquid cooling loop is in thermal contact with an exterior face (e.g., one of the major faces) of the cold plate 101, which is configured to be in thermal contact with a device (e.g., a hot-swappable device).

In some embodiments, TIM 108 is disposed on the exterior face of cold plate 101 to promote the thermal transfer of heat generated by a device (e.g., hot-swappable device) in thermal contact with the TIM 108 to cold plate 101. The TIM 108 may include an adhesive (e.g., pressure sensitive adhesive (PSA)) to physically couple the TIM 108 to the exterior face of the cold plate 101. The TIM 108 may include a non-adhesive side that is configured to come into thermal contact with a device (e.g., hot-swappable device). In some embodiments, the non-adhesive side of TIM 108 includes a liner (e.g., a metallic liner or tape liner) or any other suitable material that permits a device to be inserted or removed from a respective slot of the cooling system without damaging the TIM 108 of the apparatus 100. For a cooling system including one or more apparatus (e.g., apparatus 100), each respective apparatus corresponds to and is positioned adjacent to a slot disposed on a base plate of the cooling system. Each apparatus 100 is positioned relative to a corresponding slot such that when a device (e.g., a hot-swappable SSD device or PCIe device) is inserted to be communicatively coupled to the slot, the cold plate 101 is configured to be in thermal contact with the device.

Each apparatus 100 may include an insertion feature 110 configured to detect the insertion of a device into a slot of the cooling system and cause the cold plate 101 to avoid interference with the insertion of the device. In some embodiments, the cold plate 101 avoids interference with the insertion of the device by rotating about pin 102 to allow the device to be inserted into a slot of the cooling system. In some embodiments, the insertion feature 110 detects a translation motion of the device (e.g., hot-swappable device) during the insertion and removal of the device (e.g., an SSD device or PCIe device). When the device is fully inserted into a slot of the cooling system, apparatus 100 may be configured to apply a force, using a spring 112, causing the cold plate 101 to be in thermal contact with the device (e.g., hot-swappable device) through TIM 108. During the insertion and removal of the device, the insertion feature 110 may be configured to provide clearance between the device and the cold plate 101 of the respective apparatus 100.

Apparatus 100 may also include a spring 112 that is configured to induce a force onto the cold plate 101 causing the TIM 108 on the exterior face of the cold plate 101 to be in thermal contact with the device. In some embodiments, spring 112 induces the force onto the cold plate 101 of a respective apparatus (e.g., apparatus 100) in response to detecting the insertion of the device into a slot of the cooling system corresponding to the respective apparatus 100. Spring 112 may be of a (a) leaf spring, (b) beam spring (e.g., a cantilever beam spring), (c) torque spring, (d) electronic force-inducing component, (e) magnetic force-inducing component, or (f) electro-magnetic force-inducing component that induces a force onto the cold plate 101, causing the TIM 108 to be in thermal contact with the device. In some embodiments, the spring 112 induces a force onto the exterior face of the cold plate 101 that is opposite to the major face on which the TIM 108 is applied. The spring 112 of a respective apparatus (e.g., apparatus 100) is configured to induce a force on the cold plate 101 of the respective apparatus to reduce a thermal interface resistance between a device (e.g., hot-swappable device) and the cold plate 101. In some embodiments, the spring 112 may be any suitable force-inducing component, such as a mechanical spring component, an electrical spring component, a magnetic spring component, an electromagnetic spring component, or a gravitational spring component.

In some embodiments, each apparatus 100 may include a cold plate 101, or any suitable thermal cooling solution that uses a cooling medium (e.g., cooling liquid or vapor), such as a vapor chamber and heat pipe.

FIG. 2 shows an illustrative isometric view diagram of an apparatus, similar to that of FIG. 1, in thermal contact with a device 202, in accordance with some embodiments of the present disclosure. In some embodiments, each device 202 (e.g., hot swappable device) may include a circuitry that functions as a storage device system (e.g., an SSD storage system), which includes a storage device such as an SSD device. In some embodiments, the circuitry of device 202 may include any suitable processing circuitry, which may include any suitable processing chip (e.g., an application-specific integrated circuit (ASIC) chip) or processing core. In some embodiments, device 202 may be any suitable device that generates heat and may benefit from being placed in a thermal cooling system to reduce thermal throttling of device 202, therefore improving the performance of device 202.

In some embodiments, each device 202 may be a hot swappable device or any other suitable device that can be added or removed from a slot of the cooling system without stopping, shutting down, or rebooting the cooling system.

FIG. 3 shows an illustrative isometric view diagram of a cooling system 300 capable of cooling multiple devices (e.g., device 202), in accordance with some embodiments of the present disclosure. Cooling system 300 disclosed herein promotes thermal transfer from (a) devices (e.g., device 202) that are in thermal contact with the apparatuses (e.g., apparatus 100) to (b) the liquid cooling of the cold plates (e.g., cold plate 101) of the apparatuses, improving the overall thermal cooling capabilities of the cooling system 300. The cooling system 300 is capable of cooling one or more devices 202 (e.g., hot-swappable devices) and includes a base plate (not shown) and a slot 302 disposed on the base plate for each respective device 202 (e.g., hot-swappable device) that the cooling system is capable of thermally cooling. Each slot 302 is configured to receive and to be communicatively coupled with a connector of a respective device 202 (e.g., an SSD device or PCIe device). The cooling system 300 further includes an apparatus 100 extending from the base plate for each respective device 202 (e.g., hot-swappable device) that the cooling system 300 is capable of thermally cooling.

In some embodiments, when a cooling system 300 includes more than one apparatus 100, for each respective apparatus (e.g., apparatus 100), the liquid cooling outlet of the respective apparatus is coupled to the liquid cooling inlet of an adjacent apparatus. In such embodiments, the apparatuses of the cooling system 300 are daisy-chained together such that the cooling liquid used within a first cold plate of a first apparatus passes on to be used within a second cold plate of a second apparatus, and the cooling liquid continues to be passed through the cold plates of each other apparatus of the cooling system. In some embodiments, the apparatuses (e.g., apparatus 100) are daisy-chained, coupling the liquid cooling outlet (e.g., liquid cooling outlet 106) of a first apparatus to the liquid cooling inlet (e.g., liquid cooling inlet 104) of an adjacent apparatus using a liquid cooling connection 303. In such embodiments, the first cold plate (e.g., cold plate 101) of the first apparatus of the cooling system 300 is configured to receive cooling liquid from a cooling liquid source 304, and a last cold plate of a last apparatus of the cooling system is configured to expel the cooling liquid to a cooling liquid drain 306.

FIG. 4 shows an illustrative exploded view diagram of another apparatus 400, in accordance with some embodiments of the present disclosure. Each apparatus 400 includes a cold plate 101 including a pin 402 about which the cold plate 101 is rotatable, a liquid cooling inlet 104 to receive cooling liquid (e.g., thermal coolant), and a liquid cooling outlet 106 to expel the received cooling liquid. The cold plate 101 may include a liquid cooling loop 401 that couples the liquid cooling inlet 104 to the liquid cooling outlet 106. As shown in FIG. 4, liquid cooling loop 401 is arranged within the cold plate 101. The liquid cooling loop 401 may be arranged within the cold plate 101 of a respective apparatus (e.g., apparatus 400) such that heat transfers from (1) a device (e.g., hot-swappable device) that is in thermal contact with the respective apparatus (e.g., apparatus 400) to (2) the cooling liquid received through the liquid cooling inlet 104, passing through the liquid cooling loop 401, and thereafter expelled through the liquid cooling outlet 106. In some embodiments, the liquid cooling loop 401 is in thermal contact with an exterior face (e.g., one of the major faces) of the cold plate 101, which is configured to be in thermal contact with a device (e.g., hot-swappable device).

Each respective apparatus includes a pin 402 about which the cold plate 101 of the respective apparatus 400 may rotate. In some embodiments, each pin 402 of a respective apparatus 400 includes (1) an inlet 404 coupled to the liquid cooling inlet 104 of the respective cold plate 101 to receive liquid cooling and expel the liquid cooling into the liquid cooling inlet 104, and (2) an outlet 406 coupled to the liquid cooling outlet 106 of the respective cold plate 101 to receive cooling liquid from the liquid cooling outlet 106 and expel the cooling liquid.

The terms “an embodiment”, “embodiment”, “embodiments”, “the embodiment”, “the embodiments”, “one or more embodiments”, “some embodiments”, and “one embodiment” mean “one or more (but not all) embodiments” unless expressly specified otherwise.

The terms “including”, “comprising”, “having” and variations thereof mean “including but not limited to”, unless expressly specified otherwise.

The enumerated listing of items does not imply that any or all of the items are mutually exclusive, unless expressly specified otherwise.

The terms “a”, “an” and “the” mean “one or more”, unless expressly specified otherwise.

Devices that are in communication with each other need not be in continuous communication with each other, unless expressly specified otherwise. In addition, devices that are in communication with each other may communicate directly or indirectly through one or more intermediaries.

A description of an embodiment with several components in communication with each other does not imply that all such components are required. On the contrary a variety of optional components are described to illustrate the wide variety of possible embodiments. Further, although process steps, method steps, algorithms or the like may be described in a sequential order, such processes, methods, and algorithms may be configured to work in alternate orders. In other words, any sequence or order of steps that may be described does not necessarily indicate a requirement that the steps be performed in that order. The steps of processes described herein may be performed in any order practical. Further, some steps may be performed simultaneously.

When a single device or article is described herein, it will be readily apparent that more than one device/article (whether or not they cooperate) may be used in place of a single device/article. Similarly, where more than one device or article is described herein (whether or not they cooperate), it will be readily apparent that a single device/article may be used in place of the more than one device or article, or a different number of devices/articles may be used instead of the shown number of devices or programs. The functionality and/or the features of a device may be alternatively embodied by one or more other devices which are not explicitly described as having such functionality/features. Thus, other embodiments need not include the device itself.

At least certain operations that may have been illustrated in the figures show certain events occurring in a certain order. In alternative embodiments, certain operations may be performed in a different order, modified, or removed. Moreover, steps may be added to the above-described logic and still conform to the described embodiments. Further, operations described herein may occur sequentially or certain operations may be processed in parallel. Yet further, operations may be performed by a single processing unit or by distributed processing units.

The foregoing description of various embodiments has been presented for the purposes of illustration and description. It is not intended to be exhaustive or to be limited to the precise forms disclosed. Many modifications and variations are possible in light of the above teaching.

What is claimed is:

1. An apparatus comprising:
a cold plate comprising:
a first major face parallel to a first major plane of the cold plate,
a pin arranged along an axis that extends in a direction parallel to the major plane, wherein the cold plate is rotatable about the axis,
a liquid cooling inlet at a first end of the cold plate, and
a liquid cooling outlet at the first end of the cold plate; and
a thermal interface material (TIM) disposed on the first major face, wherein the TIM is configured to transfer heat from a device in thermal contact with the TIM to the cold plate.

2. The apparatus of claim 1, wherein:
the liquid cooling inlet is configured to receive cooling liquid, and
the liquid cooling outlet is configured to expel the received cooling liquid.

3. The apparatus of claim 2, wherein the cold plate is configured to transfer heat to the received cooling liquid.

4. The apparatus of claim 1, further comprising an insertion feature configured to:
detect an insertion of the device, and
cause the cold plate and TIM to avoid interference with the insertion of the device.

5. The apparatus of claim 1, further comprising a spring configured to:
induce a force onto the cold plate, causing the TIM to be in thermal contact with the device.

6. The apparatus of claim 5, further comprising a second major face in parallel with and opposite to the first major face, and wherein to induce the force onto the cold plate, the spring is to induce the force onto the second major face, causing the TIM to be in thermal contact with the device.

7. The apparatus of claim 5, wherein the spring is one of a (a) leaf spring, (b) cantilever beam spring, (c) torque spring, (d) electronic force-inducing component, (e) magnetic force-inducing component, and (f) electro-magnetic force-inducing component.

8. The apparatus of claim 1, wherein the TIM comprises:
a non-adhesive surface with which the device is in thermal contact, and
a liner applied to the non-adhesive surface, the liner configured to protect the TIM from damage caused by the device during insertion and removal of the device.

9. The apparatus of claim 1, wherein the device is a solid-state drive (SSD).

10. The apparatus of claim 1, wherein the pin comprises:
an inlet coupled to the liquid cooling inlet, wherein the inlet is configured to:
receive cooling liquid, and
expel the cooling liquid to the liquid cooling inlet; and
an outlet coupled to the liquid cooling outlet, wherein the outlet is configured to:
receive the cooling liquid from the liquid cooling outlet, and
expel the cooling liquid.

11. A cooling system capable of cooling one or more devices, the cooling system comprising:
a base plate; and
for each respective device of the one or more devices:
a slot disposed on the base plate, wherein the slot is configured to communicatively couple to a connector of the respective device; and
an apparatus extending from the base plate, the apparatus comprising:
a cold plate comprising:
a first major face parallel to a first major plane of the cold plate,
a pin arranged along an axis that extends in a direction parallel to the major plane, wherein the cold plate is rotatable about the axis,
a liquid cooling inlet at a first end of the cold plate, and
a liquid cooling outlet at the first end of the cold plate; and
a thermal interface material (TIM) disposed on the first major face, wherein the TIM is configured to transfer heat from the respective device in thermal contact with the TIM to the cold plate.

12. The cooling system of claim 11, wherein for each apparatus:
the liquid cooling inlet is configured to receive cooling liquid, and
the liquid cooling outlet is configured to expel the received cooling liquid.

13. The cooling system of claim 12, wherein for each apparatus, the cold plate is configured to transfer heat to the received cooling liquid.

14. The cooling system of claim 11, wherein each apparatus further comprises an insertion feature configured to:
detect an insertion of the respective device, and
cause the cold plate and TIM to avoid interference with the insertion of the respective device.

15. The cooling system of claim 11, wherein each apparatus further comprises a spring configured to induce a force onto the cold plate, causing the TIM to be in thermal contact with the respective device.

16. The cooling system of claim 15, wherein each apparatus further comprises a second major face in parallel with and opposite to the first major face, and wherein to induce the force onto the cold plate, the spring is to induce the force onto the second major face, causing the TIM to be in thermal contact with the respective device.

17. The cooling system of claim 15, wherein for each apparatus, the spring is one of a (a) leaf spring, (b) cantilever beam spring, (c) torque spring, (d) electronic force-inducing component, (e) magnetic force-inducing component, and (f) electro-magnetic force-inducing component.

18. The cooling system of claim 11, wherein the TIM of each respective device comprises:
a non-adhesive surface with which the respective device is in thermal contact, and
a liner applied to the non-adhesive surface, the liner configured to protect the TIM from damage caused by the respective device during:
insertion of the respective device into a respective slot, and
removal of the respective device from the respective slot.

19. The cooling system of claim 11, wherein each respective device of the one or more devices is a solid-state drive (SSD).

20. The cooling system of claim 11, wherein for each apparatus, the pin comprises:
an inlet coupled to the liquid cooling inlet, wherein the inlet is configured to:
receive cooling liquid, and
expel the cooling liquid to the liquid cooling inlet; and
an outlet coupled to the liquid cooling outlet, wherein the outlet is configured to:
receive the cooling liquid from the liquid cooling outlet, and
expel the cooling liquid.
